(19) United States
(12) Patent Application Publication
(10) Pub. No.: US 2018/0175189 A1
(43) Pub. Date: Jun. 21, 2018

(54) SEMICONDUCTOR DEVICE INCLUDING AUXILIARY STRUCTURE

(71) Applicant: SANKEN ELECTRIC CO., LTD., Niiza-Shi (JP)

(72) Inventors: Shunsuke FUKUNAGA, Saitama-Shi (JP); Taro KONDO, Niiza-Shi (JP)

(73) Assignee: SANKEN ELECTRIC CO., LTD., Niiza-Shi (JP)

(21) Appl. No.: 15/385,214

(22) Filed: Dec. 20, 2016

(51) Int. Cl. H01L 29/78; H01L 29/423; H01L 29/10; H01L 29/06

(52) U.S. Cl. CPC H01L 29/7813; H01L 29/4236; H01L 29/0684; H01L 29/7827; H01L 29/0615; H01L 29/1095

(57) ABSTRACT

One or more embodiments disclose a semiconductor device that includes a trench extending into a drift zone of a semiconductor body from a surface of the semiconductor body in a first direction; a dielectric structure in the trench; a gate electrode in the dielectric structure; a body region of a first conductivity type other than a second conductivity type of the drift zone; and an auxiliary structure of the second conductivity type adjoining the drift zone, the body region and the dielectric structure, wherein the auxiliary structure extends outwardly from the trench in a second direction, the second direction orthogonal to the first direction, and in the second direction, a first length of the auxiliary structure is larger than a second length of the trench.

### TECHNICAL FIELD

The disclosure relates to a semiconductor device.

### BACKGROUND

The development of new generations of semiconductor components, in particular of vertical power semiconductor components, is driven by the goal of increasing a switching speed of switching elements, e.g. Field Effects Transistors (FETs), and reducing the so-called specific on-resistance Ron (resistance per unit area). Reducing Ron allows to minimize the static power loss and to provide power semiconductor components having a higher current density. It is thereby possible to use smaller and hence more cost-effective semiconductor components for the same total current.

It is desirable to provide an improved trade-off between the specific on-resistance Ron of semiconductor components and their switching speed.

### SUMMARY

One or more embodiments disclose a semiconductor device that includes a trench extending into a drift zone of a semiconductor body from a surface of the semiconductor body in a first direction; a dielectric structure in the trench; a gate electrode in the dielectric structure; a body region of a first conductivity type other than a second conductivity type of the drift zone; and an auxiliary structure of the second conductivity type adjoining the drift zone, the body region and the dielectric structure, wherein the auxiliary structure extends outwardly from the trench in a second direction, the second direction orthogonal to the first direction, and in the second direction, a first length of the auxiliary structure is larger than a second length of the trench.

According to the one or more embodiments, it is possible to provide a semiconductor device having an improved switching speed and a reduced on-resistance.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of the invention and are incorporated in and constitute a part of the specification. The drawings illustrate embodiments of the invention and together with the description serve to explain principles of the invention. Other embodiments of the invention and many of the intended advantages will be readily appreciated as they become better understood by reference to the following detailed description. The elements of the drawings are not necessarily to scale relative to each other. Like reference numerals designate corresponding similar parts.

FIG. 1 illustrates a schematic cross-sectional view of a semiconductor device according to one or more embodiments;

FIG. 2 illustrates a schematic cross-sectional view of a semiconductor device according to one or more embodiments;

FIG. 3 illustrates a schematic cross-sectional view of a semiconductor device according to one or more embodiments;

FIG. 4 illustrates a schematic cross-sectional view of a semiconductor device according to one or more embodiments; and

FIG. 5 illustrates a schematic cross-sectional view of a semiconductor device according to one or more embodiments.

### DETAILED DESCRIPTION

Embodiments are explained with referring to drawings. In the respective drawings referenced herein, the same constituents are designated by the same reference numerals and duplicate explanation concerning the same constituents may be omitted. All of the drawings are provided to illustrate the respective examples only. No dimensional proportions in the drawings shall impose a restriction on the embodiments. For this reason, specific dimensions and the like should be interpreted with the following descriptions taken into consideration. In addition, the drawings include parts whose dimensional relationship and ratios are different from one drawing to another.

As employed in the specification, the term “electrically coupled” is not meant to mean that the elements must be directly coupled together. Instead, intervening elements may be provided between the “electrically coupled” elements. As an example, none, part, or all of the intervening element(s) may be controllable to provide a low-ohmic connection and, at another time, a non-low-ohmic connection between the “electrically coupled” elements. The term “electrically connected” intends to describe a low-ohmic electric connection between the elements electrically connected together, e.g., a connection via a metal and/or highly doped semiconductor.

Some Figures refer to relative doping concentrations by indicating “−” or “+” next to the doping type. For example, “n⁻ ” means a doping concentration which is less than the doping concentration of an “n”-doping region while an “n⁺”-doping region has a larger doping concentration than the “n”-doping region. Doping regions of the same relative doping concentration may or may not have the same absolute doping concentration. For example, two different n⁺-doped regions can have different absolute doping concentrations. The same applies, for example, to an n⁻-doped and a p⁺-doped region. In the embodiments described below, a conductivity type of the illustrated semiconductor regions is denoted n-type or p-type, in more detail one of n⁻-type, n-type, n⁺-type, p⁻-type, p-type and p⁺-type. In each of the illustrated embodiments, the conductivity type of the illustrated semiconductor regions may be vice versa. In other words, in an alternative embodiment to any one of the embodiments described below, an illustrated p-type region may be n-type and an illustrated n-type region may be p-type.

Terms such as “first”, “second”, and the like, are used to describe various structures, elements, regions, sections, etc. and are not intended to be limiting. Like terms refer to like elements throughout the description.

The terms “having”, “containing”, “including”, “comprising” and the like are open and the terms indicate the presence of stated elements or features, but not preclude additional elements or features. The articles “a”, “an” and “the” are intended to include the plural as well as the singular, unless the context clearly indicates otherwise.

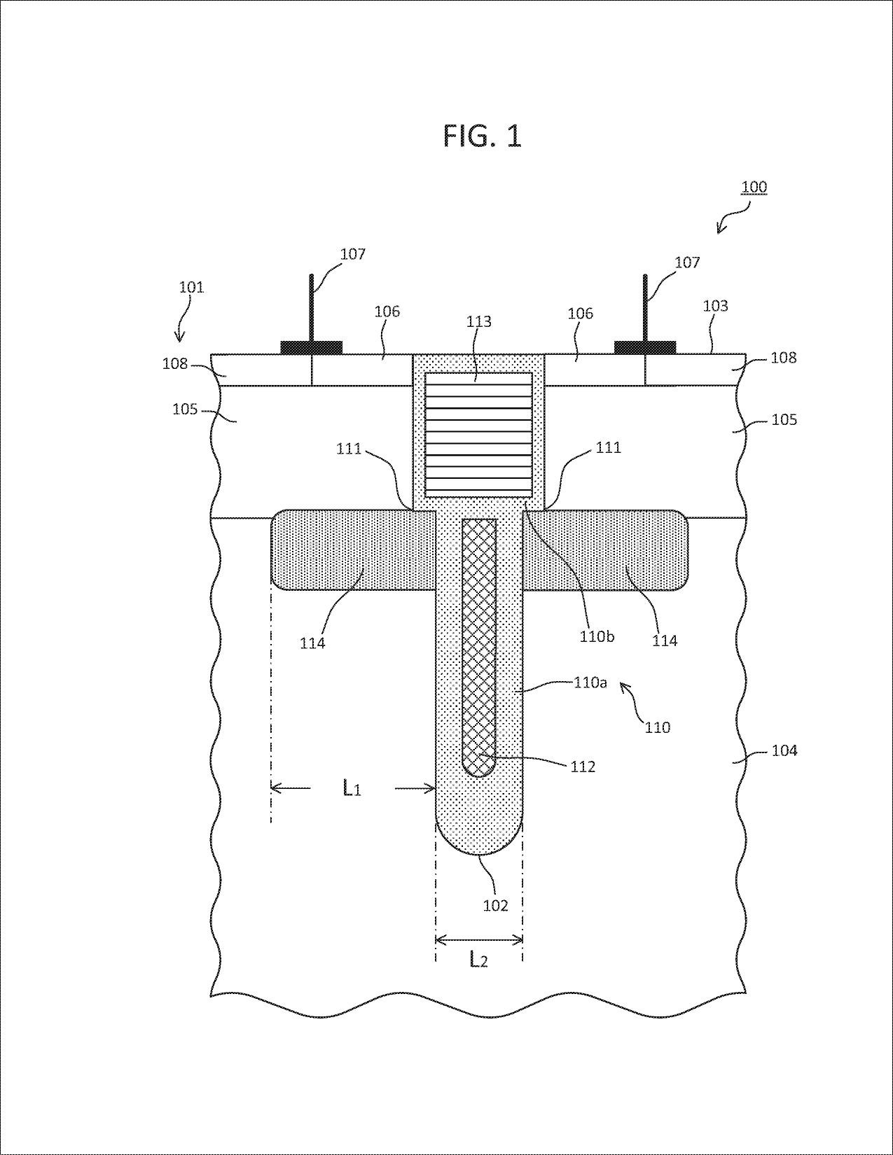

FIG. 1 illustrates a cross-section of a part of a semiconductor device 100 according to an embodiment. The semiconductor device 100 includes a semiconductor body 101. A trench 102 extends into the semiconductor body 101 from a surface 103. An n⁻-type drift zone 104 adjoins a lower part of the trench 102. A p-type body region 105 adjoins an upper part of the trench 102. An n⁺-type source region 106 is arranged in the p-type body region 105 and adjoins the trench 102. The n⁺-type source region 106 is electrically coupled to a contact 107 on the surface 103. The contact 107 is illustrated in a simplified manner and may include a conductive material in contact with the surface 107, e.g. a conductive plug or a conductive line including one or more of doped semiconductor material(s), silicide(s), metal(s). The p-type body region 105 is electrically coupled to the contact 107 via a p⁺-type body contact zone 108.

In the semiconductor device 100, the source region 106 and the drift zone 104 are doped with a dopant of a first conductivity type in this embodiment, for example arsenic (As) for an n-type doping. However, phosphorus (P), sulphur (S) and/or antimony (Sb) can be used as the n-type dopant. By contrast, the body region 105 and the body contact zone 108 are doped with a dopant of a second conductivity type such as, for example boron (B), aluminum (Al) and/or indium (In) as p-type dopant. Depending on the dopant used for the individual regions, therefore, an n-channel or p-channel field effect transistor may be formed as the semiconductor device 100. In the semiconductor device 100, the n-type drift zone 104 may adjoin an n⁺-type drain (not illustrated in FIG. 1) at a second surface opposite to the surface 103. The second surface may constitute a rear side of the semiconductor body 101 and the surface 103 may constitute a front side of the semiconductor body 101. According to another embodiment, the n⁺-type drain (not illustrated in FIG. 1) may be arranged as an up-drain at the surface 103.

In the trench 102, a dielectric structure 110 is arranged. The dielectric structure 110 includes a first dielectric part 110a and a second dielectric part 110b. The first dielectric part 110a is arranged in the lower part of the trench 102. The second dielectric part 110b is arranged in the upper part of the trench 102. The first dielectric part 110a includes in its inside a field electrode 112. The second dielectric part 110b includes in its inside a gate electrode 113. The first dielectric part 110a and the second dielectric part 110b include the same material as each other, for example one or more electrically insulating materials such as oxide and/or nitride. As an example, the first dielectric part 110a and the second dielectric part 110b may include a thermal oxide. When forming the thermal oxide, semiconductor material of the semiconductor body 101 surrounding the upper part of the trench 102 is oxidized leading to a step 111 at a bottom side of the second dielectric part 110b.

Highly doped polysilicon is one example for a material used for the gate electrode 113 and/or field electrode 112, but any other conductive material such as, for example, metal silicide, metal or the like can also be used. A portion of the dielectric structure 110 that is interposed between the gate electrode 113 and the body region 105 constitutes a gate dielectric.

The semiconductor device 100 includes an auxiliary part 114. The auxiliary part 114 is doped with the same dopant as the dopant used for the drift zone 104. A conductivity type of the auxiliary part 114 is the same as the conductivity type (n-type) of the drift zone 104. That is, the auxiliary part 114 is a semiconductor layer having a conductivity type that is different from the conductivity type of the p-type body region 105. As an example, the auxiliary part 114 may be formed by selective epitaxial growth. As a further example, the auxiliary part 114 may include a doped glass. As another example, the auxiliary part 114 may include recrystallized doped semiconductor material.

The auxiliary part 114 is in contact with a side surface of the first dielectric part 110a in the trench 102. The auxiliary part 114 extends in the p-type body region 105 and the drift zone 104 from the first dielectric part 110a to an outside of the trench 102. A top surface of the auxiliary part 114 is in contact with the step 111.

A borderline between the auxiliary part 114 and the drift zone 104 may be that line where an n-doping of the auxiliary part 114 exceeds the n-doping within the drift zone 104 by at least 30%. For example, a doping concentration of the auxiliary part 114 may be equal to or more than 1×10¹⁶ ions/cm³ but less than 5×10¹⁸ ions/cm³. Formation of the auxiliary part 114 allows a) minimizing a gate to drain charge Qgd by adjusting a first distance d₁ from the surface 103 to a location where an interface between the drift zone 104 and the body region 105 adjoins the auxiliary part 114 larger than a second distance d2 from the surface 103 to a bottom side of the gate electrode 113 at a location where the gate electrode 113 adjoins the auxiliary part 114, and b) reducing the specific on-resistance Ron by adjusting a channel end, i.e. a top side of the auxiliary part 114, at or above a bottom side of the gate dielectric. The distances d₁ and d₂ refer to a same top level and in case of a curved surface 103, d₁ and d₂ may refer to an uppermost level of the semiconductor body 101. A lateral dose of the auxiliary part 114 may be set below a breakdown charge, e.g. several 10¹² cm⁻².

Here, as illustrated in FIG. 1, the auxiliary part 114 has a length L1 in a direction in which the n⁺-type source region 106 and the p⁺-type body contact zone 108 are aligned. For example, the length L1 is set to be 0.3 micrometers to 20 micrometers. The trench 102 has a length L2 in the direction in which the n⁺-type source region 106 and the p⁺-type body contact zone 108 are aligned. Here, the length L1 is larger than the length L2. In the semiconductor device 100, as the length L1 of the auxiliary part 114 becomes larger, a channel width becomes larger. Thus, in the semiconductor device 100, the on-resistance Ron can be reduced due to increased channel width.

Note that two auxiliary parts 114 sandwiching the trench 102 may have different doping concentrations or may have approximately the same doping concentration as each other. When the two auxiliary parts 114 sandwiching the trench 102 have the same doping concentration as each other, an electrical characteristic becomes stable.

The semiconductor device 100 may be a field effect transistor (FET) such as a metal oxide semiconductor FET (MOSFET), for example.

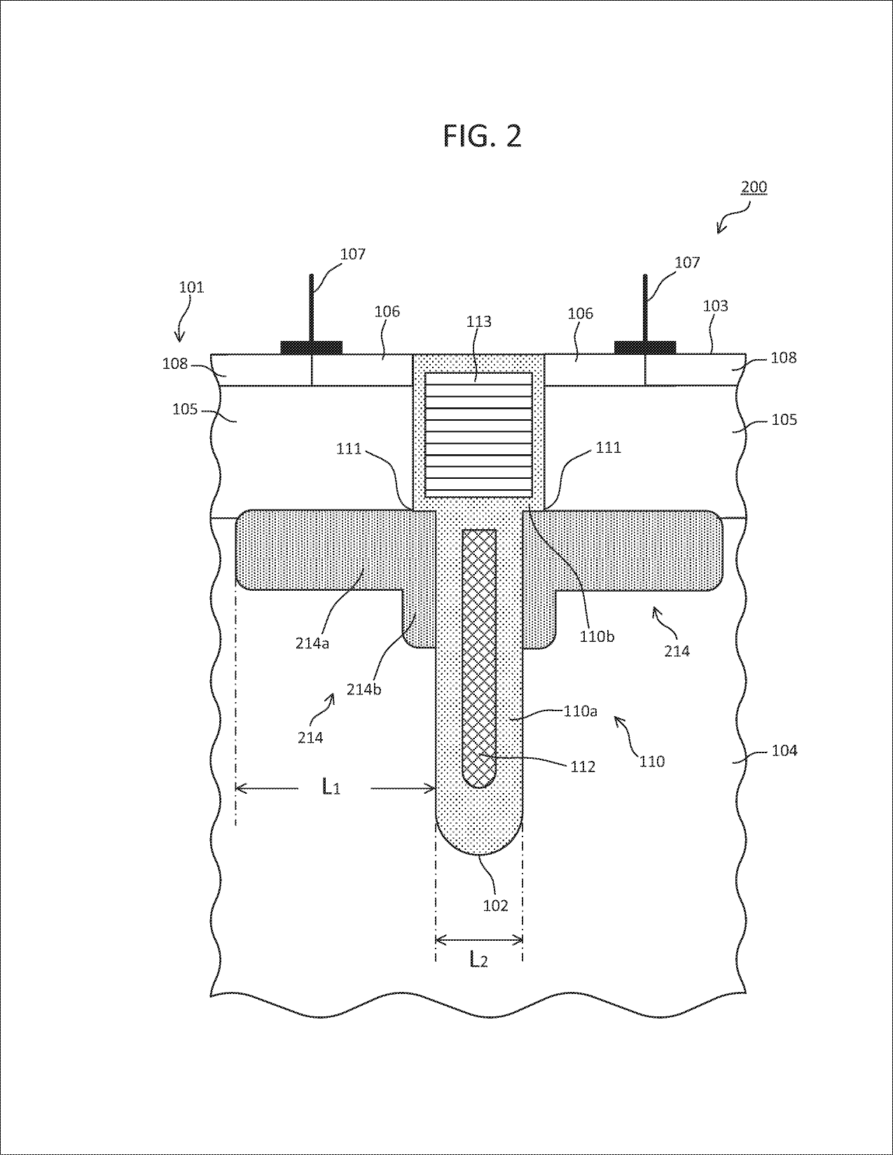

Next, a semiconductor device 200 according to a second embodiment of the invention is described below with reference to FIG. 2. The semiconductor device 200 is different from the semiconductor device 100 according to the first embodiment described above in that the semiconductor device 200 has an auxiliary structure 214 instead of the auxiliary part 114. Duplicate explanation concerning the same configurations is omitted.

Specifically, the auxiliary structure 214 includes a first auxiliary part 214a and a second auxiliary part 214b. The first auxiliary part 214a has the same configuration as the configuration of the auxiliary part 114 according to the first embodiment. In the second embodiment, the second auxiliary part 214b extends downwardly along a side surface of the first dielectric part 110a in the trench 102 from the first auxiliary part 214a. A length of the second auxiliary part 214b in the direction in which the n⁺-type source region 106 and the p⁺-type body contact zone 108 are aligned is smaller than a length L1 of the first auxiliary part 214a. Due to this configuration, the auxiliary structure 214 has a letter “L”-shaped cross-section as a whole, as illustrated in FIG. 2.

In the semiconductor device 200 according to the second embodiment, the second auxiliary part 214b extends downwardly from the first auxiliary part 214a. Therefore, a low resistance region becomes larger. Thereby, the on-resistance Ron can be reduced further.

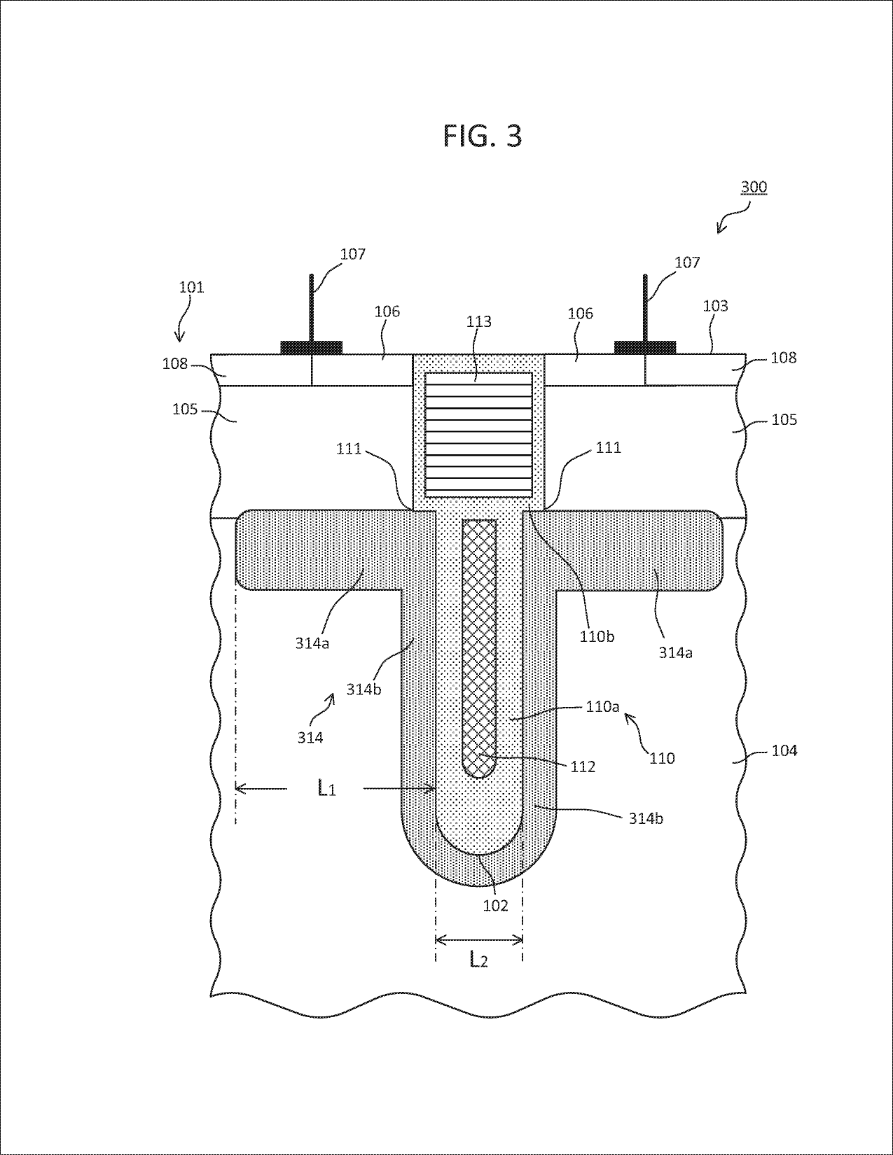

Next, a semiconductor device 300 according to a third embodiment of the invention is described below with reference to FIG. 3. The semiconductor device 300 is different from the semiconductor device 200 according to the second embodiment in that the semiconductor device 300 has an auxiliary structure 314 instead of the auxiliary structure 214. Duplicate explanation concerning the same configurations is omitted.

Specifically, the auxiliary structure 314 includes a first auxiliary part 314a and a second auxiliary part 314b. The first auxiliary part 314a has the same configuration as the configuration of the first auxiliary part 214a according to the second embodiment. The second auxiliary part 314b is different from the second auxiliary part 214b according to the second embodiment in that the second auxiliary part 314b extends along a side surface and a bottom surface of the first dielectric part 110a in the trench 102. Thus, the auxiliary structure 314 surrounds the first dielectric part 110a in the trench 102. That is, the auxiliary structure 314 surrounds a lower part of the trench 102. Therefore, in the semiconductor device 300 according to the third embodiment, a low resistance region becomes larger. Thereby, the on-resistance Ron can be reduced further.

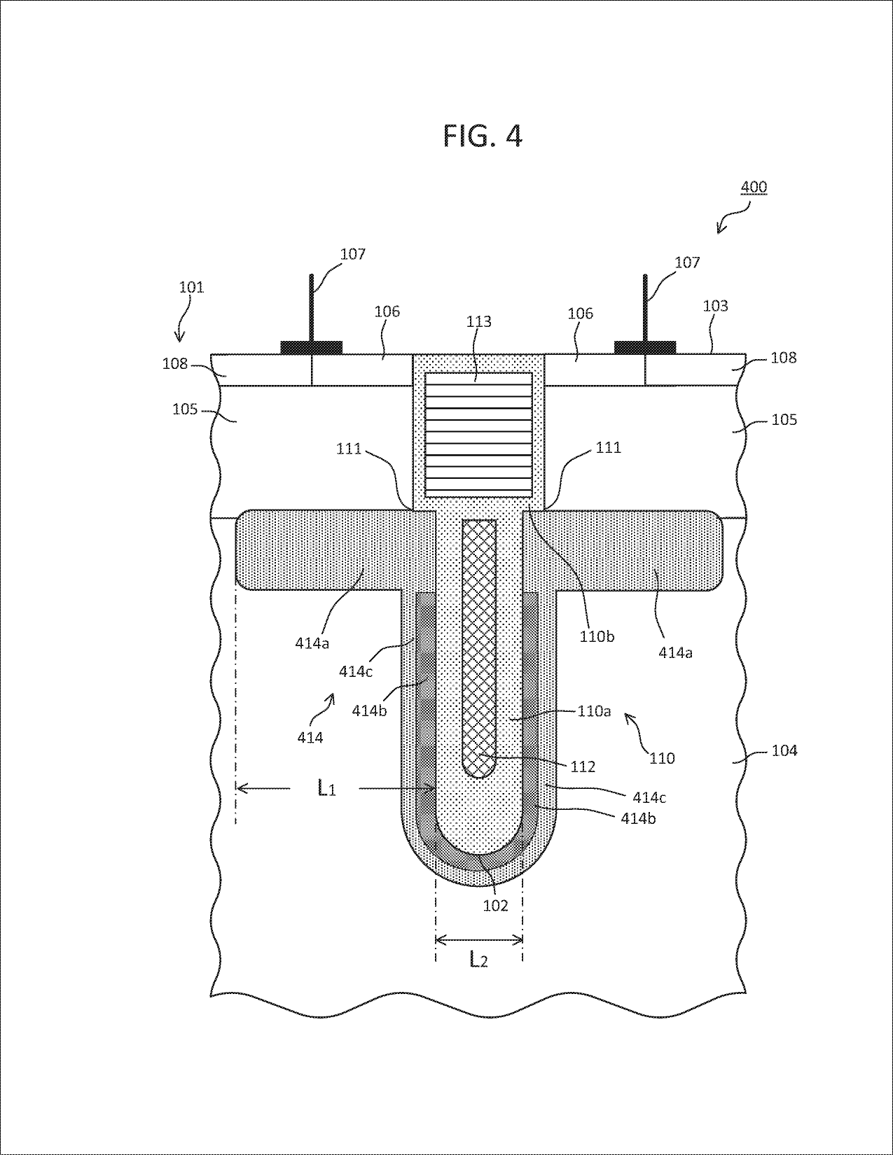

Next, a semiconductor device 400 according to a fourth embodiment of the invention is described below with reference to FIG. 4. The semiconductor device 400 is different from the semiconductor device 300 according to the third embodiment in that the semiconductor device 400 has an auxiliary structure 414 instead of the auxiliary structure 314. Duplicate explanation concerning the same configurations is omitted.

Specifically, the auxiliary structure 414 includes a first auxiliary part 414a, a second auxiliary part 414b, and a third auxiliary part 414c. The first auxiliary part 414a has the same configuration as the configuration of the first auxiliary part 314a according to the third embodiment. The second auxiliary part 414b has the same configuration as the configuration of the second auxiliary part 314b according to the third embodiment. The third auxiliary part 414c covers a surface of the second auxiliary part 414b outside of the trench 102. Thereby, side and bottom surfaces of the first dielectric part 110a in the trench 102 are covered with a two-layer structure of the second auxiliary part 414b and the third auxiliary part 414c.

Here, a doping concentration dc2 of the second auxiliary part 414b is higher than a doping concentration dc3 of the third auxiliary part 414c. The doping concentration dc2 and the doping concentration dc3 are both higher than a doping concentration of the drift zone 104. Due to this configuration, in the semiconductor device 400, a depletion layer extends gradually downwardly. As a result, in the semiconductor device 400, switching noise is suppressed. Therefore, in the semiconductor device 400 according to the fourth embodiment, the on-resistance Ron is small, and switching noise is suppressed. Note that the structure which covers side and bottom surfaces of the trench 102 is not limited to a two-layer structure, and may be a three or more-layer structure. When a three or more-layer structure covers the side and bottom surfaces of the trench 102, a layer closer to the trench 102 has a higher doping concentration.

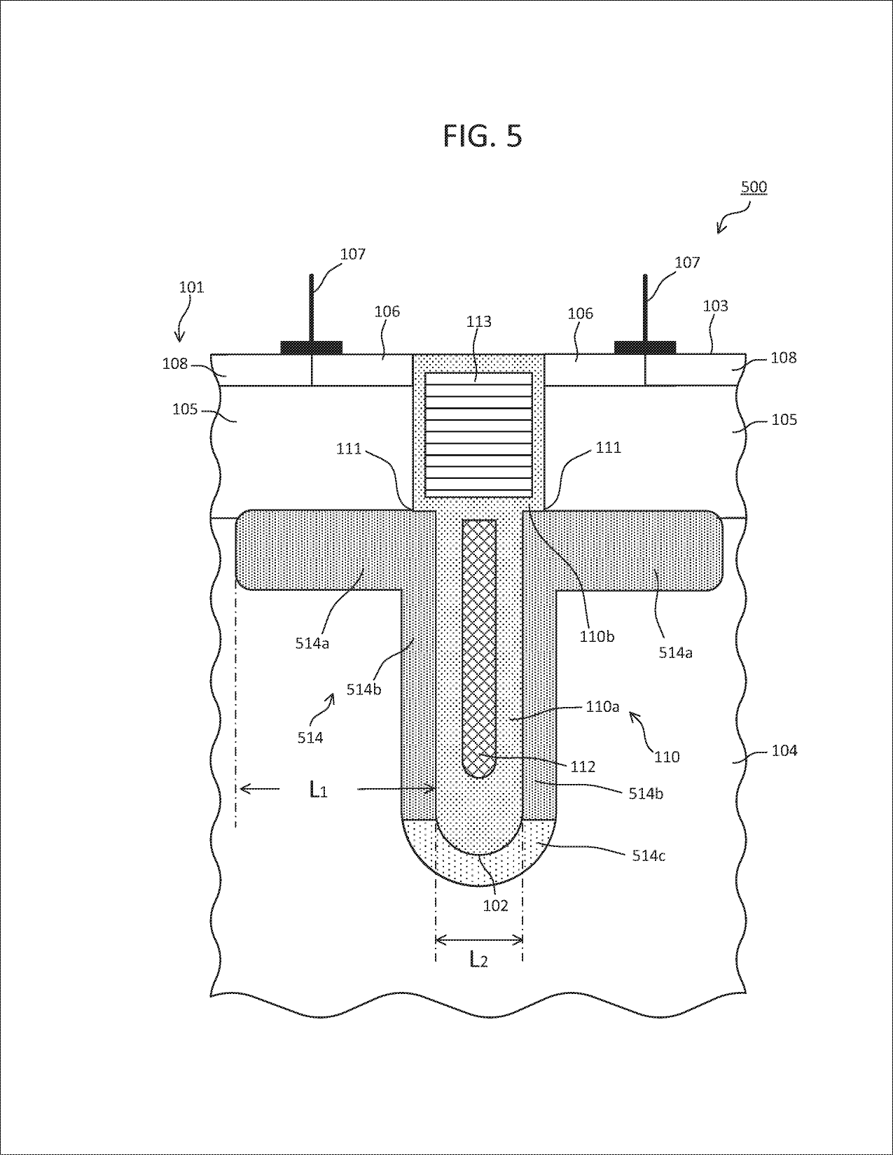

Next, a semiconductor device 500 according to a fifth embodiment of the invention is described below with reference to FIG. 5. The semiconductor device 500 is different from the semiconductor device 300 according to the third embodiment in that the semiconductor device 500 has an auxiliary structure 514 instead of the auxiliary structure 314. Duplicate explanation concerning the same configurations is omitted.

Specifically, the auxiliary structure 514 includes a first auxiliary part 514a, a second auxiliary part 514b, and a third auxiliary part 514c. The first auxiliary part 514a has the same configuration as the configuration of the first auxiliary part 314a according to the third embodiment. The second auxiliary part 514b and the third auxiliary part 514c as a whole cover side and bottom surfaces of the first dielectric part 110a in the trench 102. More specifically, the second auxiliary part 514b covers a side surface of the first dielectric part 110a in the trench 102, and the third auxiliary part 514c covers a bottom surface of the first dielectric part 110a in the trench 102. That is, the third auxiliary part 514c covers a bottom surface having a large curvature of the trench 102. Here, a doping concentration of the third auxiliary part 514c is lower than a doping concentration of the second auxiliary part 514b. Note that the doping concentration of the third auxiliary part 514c is higher than a doping concentration of the drift zone 104. Thereby, electric-field concentration below the first dielectric part 110a in the trench 102 can be suppressed. As a result, a dielectric strength voltage of the semiconductor device 500 becomes higher.

1. A semiconductor device comprising:
a trench extending into a drift zone of a semiconductor body from a surface of the semiconductor body in a first direction;
a dielectric structure in the trench;
a gate electrode in the dielectric structure;
a field electrode positioned deeper than the gate electrode in the trench;
a body region of a first conductivity type other than a second conductivity type of the drift zone; and
an auxiliary structure of the second conductivity type adjoining the drift zone, the body region and the dielectric structure, wherein
the auxiliary structure extends outwardly from the trench in a second direction, the second direction orthogonal to the first direction, the auxiliary structure is opposed to the field electrode in the second direction; and
in the second direction, a first length of the auxiliary structure is larger than a second length of the trench.

2. The semiconductor device according to claim 1, wherein the first length is from 0.3 to 20 micrometers.

3. The semiconductor device according to claim 1, wherein
the auxiliary structure includes a first auxiliary part and a second auxiliary part,
the first auxiliary part extends outwardly from the trench in the second direction, and
the second auxiliary part extends along a side surface of the trench from the first auxiliary part in the first direction.

4. The semiconductor device according to claim 3, wherein the second auxiliary part extends along a bottom surface of the trench such that the auxiliary structure surrounds a lower part of the trench.

5. The semiconductor device according to claim 4, wherein
the second auxiliary part has two-layer structure including an inner layer adjoining the side surface and the bottom surface of the trench, and an outer layer disposed on the inner layer, and
a doping concentration of the inner layer is higher than a doping concentration of the outer layer.

6. The semiconductor device according to claim 4, wherein
the bottom surface of the trench is curved,
a lower part of the second auxiliary part is in contact with the bottom surface of the trench, and
a doping concentration of the lower part of the second auxiliary part is higher than a doping concentration of another part of the second auxiliary part.

7. The semiconductor device according to claim 1, wherein
the auxiliary structure includes two auxiliary parts sandwiching the trench in the first direction, and
the two auxiliary parts have the same doping concentration as each other.

8. The semiconductor device according to claim 3, wherein a cross section of the auxiliary structure has a letter ‘L’ shape.

9. The semiconductor device according to claim 1, wherein
a conductivity type of the auxiliary structure is different from a conductivity type of the body region, and
a doping concentration of the auxiliary structure is higher than a doping concentration of the drift zone.
